(19) United States
(12) Patent Application Publication
(10) Pub. No.: US 2007/0029193 A1
(43) Pub. Date: Feb. 8, 2007

(54) Segmented biased peripheral electrode in plasma processing method and apparatus

(75) Inventor: Jozef Brcka, Loudonville, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited

(21) Appl. No.: 11/196,557

(22) Filed: Aug. 3, 2005

(51) Int. Cl. C23C 14/00

(52) U.S. Cl. 204/298.02

(57) ABSTRACT

A system and method for enhancing the plasma etch process uniformity in an ionized PVD semiconductor wafer processing system is provided. The system and method controls chamber conditions so as to produce highly uniform processing for a deposition-etch process sequence and yielding improved coverage capabilities of high aspect ratio (HAR) features when the deposition and etch steps are performed within same processing chamber. Plasma is generated and maintained by an inductively coupled plasma (ICP) source. In the deposition portions of the process, metal or other coating material is produced from a target of a PVD source. A segmented peripheral electrode surrounds the wafer at a distance from its outer edge. RF induced bias is applied to the electrode, cycling around the segment so as to subject each to a duty cycle controlled by a processor. The tendency of the etching or sputtering of the wafer surface that occurs with deposition to produce a radially selective coverage of the wafer, particularly of inside features and the flat field of the wafer, are offset by the bias electrode. A segmented biased-ring electrode is controlled to provide conditions for azimuthal improvement of etch rate and overall etch rate uniformity across the wafer.

The present application is related to U.S. patent application Ser. No. 10/454,381 (filed Jun. 4, 2003, Pub. US 2005/0103444), Ser. No. 10/717,268 (filed Nov. 19, 2003, Pub. US 2005/0103445) and Ser. No. 10/766,505 (filed Jul. 28, 2004), each hereby expressly incorporated by reference herein.

### FIELD OF THE INVENTION

This invention relates to high-density plasma generating devices, systems and processes, particularly for the manufacture of semiconductor wafers. This invention particularly relates to the high density inductively coupled plasma sources used in semiconductor processing.

### BACKGROUND OF THE INVENTION

For the deposition of films onto high aspect ratio, submicron-featured semiconductor wafers, an ionized physical vapor deposition (iPVD) process and apparatus are useful. Apparatus having the features as described in U.S. Pat. Nos. 6,287,435, 6,080,287, 6,197,165, 6,132,564 are particularly well suited for the sequential or instant deposition and etching process. Sequential deposition and etching process can be applied to a substrate in the same process chamber without breaking vacuum or moving the wafer from chamber to chamber. The configuration of the apparatus allows rapid change from ionized PVD deposition mode to etching mode or from etching mode to ionized PVD deposition mode. The configuration of the apparatus also allows for the simultaneous optimization of ionized PVD deposition process control parameters during deposition mode and etching process control parameters during etching mode. The consequence of these advantages is a high throughput of wafers with superior via metallization and subsequent electroplated fill operation.

Of the advantages of ionized PVD systems, there are still some constraints to utilization of the system at the maximum of its performance. For example, existing hardware does not allow optimizing uniformity for both deposition and etch processes simultaneously over a wide process pressure window. While an annular target provides excellent conditions for flat field deposition uniformity, the use of large area inductively coupled plasma (ICP) to generate a large size low-pressure plasma for uniform etch process is geometrically limited. While an ICP source that is axially aligned with the substrate is optimal to ionize metal vapor sputtered from the target and to fill features in the center of the wafer therewith, it often produces an axially peaked high-density plasma profile that does not provide a uniform etch in a deposition and etch process or in a no-net-deposition (NND) process. Etching occurs at an increased bias at the wafer so deposited metal (TaN/Ta for adhesion and barrier properties, and/or Cu as seed layer) is simultaneously removed from the flat field area of the wafer during deposition, but remains deposited at the sidewalls of the feature. The net process leaves the deposition of a thin film at the bottom of the feature.

The deposition and etch process benefits from either a fully identical nonuniformity distribution of the etch and the deposition processes, or highly uniform processes. To create identical conditions at the wafer to improve the symmetry of coverage and reduce non-uniformity at the wafer, single, continuous, biased rings or focusing rings have been employed. These involve the use of axially symmetric approaches that in some cases have improved radial uniformity, but are not effective in the case of azimuthal non-uniformity. Azimuthal nonuniformity can be generated, for example, by interaction of the static magnetic field from metal source, ICP antenna geometry and RF feeds location, thermal and RF performance of the substrate holder, deposition shields, gas flow, and other causes.

Accordingly, there is a need for an ICP source that produces a high density uniform plasma that is simple and low in cost.

### SUMMARY OF THE INVENTION

An objective of the present invention is to generate and control plasma that will contribute to the uniform plasma processing in simultaneous or sequential deposition and etching processes used for high aspect ratio feature coverage by ionized PVD, particularly for 300 mm wafers.

Another objective of the present invention is to provide an azimuthally symmetric plasma and a control therefor to compensate for azimuthal nonuniformity.

According to principles of the present invention, a plasma column is off-set azimuthally around the wafer in a changing manner, resulting in an increase in the uniformity of coverage from a deposition and etch sequence.

According to certain embodiments of the invention, a biased, segmented device is used to allow azimuthal control of the non-uniformity. The device may employ peripheral, electrically-biased segments around the wafer to geometrically control the flux from the plasma.

According to some embodiments of the invention, a multi-segmented ring-shaped electrode is provided for reducing non-uniformities in a semiconductor plasma processing apparatus that is dimensioned to encircle a substrate support. Electrical energy is coupled to each of the segments of the electrode and a controller is programmed to sequentially energize the segments of the electrode.

The electrode may be included in a semiconductor wafer processing apparatus having a vacuum processing chamber, a sputtering target in the chamber, a high-density plasma source coupled to the chamber, and a substrate support in the chamber with the electrode encircling the substrate support. Electrical energy is coupled to segments of the electrode to sequentially energize the segments of the electrode.

Azimuthal uniformity of a film applied in an ionized physical vapor deposition (iPVD) process is improved by encircling a substrate support with the segmented element and cyclically energizing the segmented element by sequentially coupling electrical energy to the segments.

In some embodiments, the ratio of the biased surface area of the element exposed by plasma is changed to effect the symmetry of the plasma column inside the processing chamber.

In the illustrated embodiment, the device is provided with a minimum of three segments, which are dynamically biased to have a rotational impact on the plasma column. To provide more effective control of plasma uniformity, more segments can be used, with six to eight segments providing an upper practical limit, but a higher number can be used.

The segments of the device may be biased at various cycling frequencies, may be biased with various duty cycles at each segment, and may be biased at various phase shifts from segment to segment. In this way a completely customized effect on the plasma column can be produced to compensate for azimuthal non-uniformities that would be otherwise present in a particular plasma processing system. Either RF or DC power can be applied to power segments.

These and other objects and advantages of the present invention will be more readily apparent from the following detailed description of illustrated embodiments of the invention.

### BRIEF DESCRIPTION OF THE DRAWINGS

FIG. 1 is a cross sectional diagram of a prior art ionized physical vapor deposition apparatus of one type to which certain embodiments of the present invention can be applied.

FIG. 2A is a simplified diagrammatic cross sectional view of a processing system according to certain embodiments of the present invention.

FIG. 2B is a diagrammatic cross sectional view, similar to FIG. 2A, of a processing system according to other embodiments of the present invention.

FIG. 3A is a perspective diagram illustrating one embodiment of the biased electrode of the system of FIG. 2A.

FIG. 3B is a perspective diagram illustrating another embodiment of the biased electrode of the system of FIG. 2A.

FIG. 3C is an enlarged perspective diagram illustrating a portion of the biased electrode of FIGS. 3A and 3B.

FIG. 4A is a perspective diagram illustrating one embodiment of the biased electrode of the system of FIG. 2B.

FIG. 4B is a perspective diagram illustrating another embodiment of the biased electrode of the system of FIG. 2B.

FIG. 4C is an enlarged perspective diagram illustrating a portion of the biased electrode of FIG. 4A.

FIGS. 5A-5D are graphs illustrating certain alternative biasing sequences for electrodes according to certain exemplary embodiments of the present invention.

### DETAILED DESCRIPTION

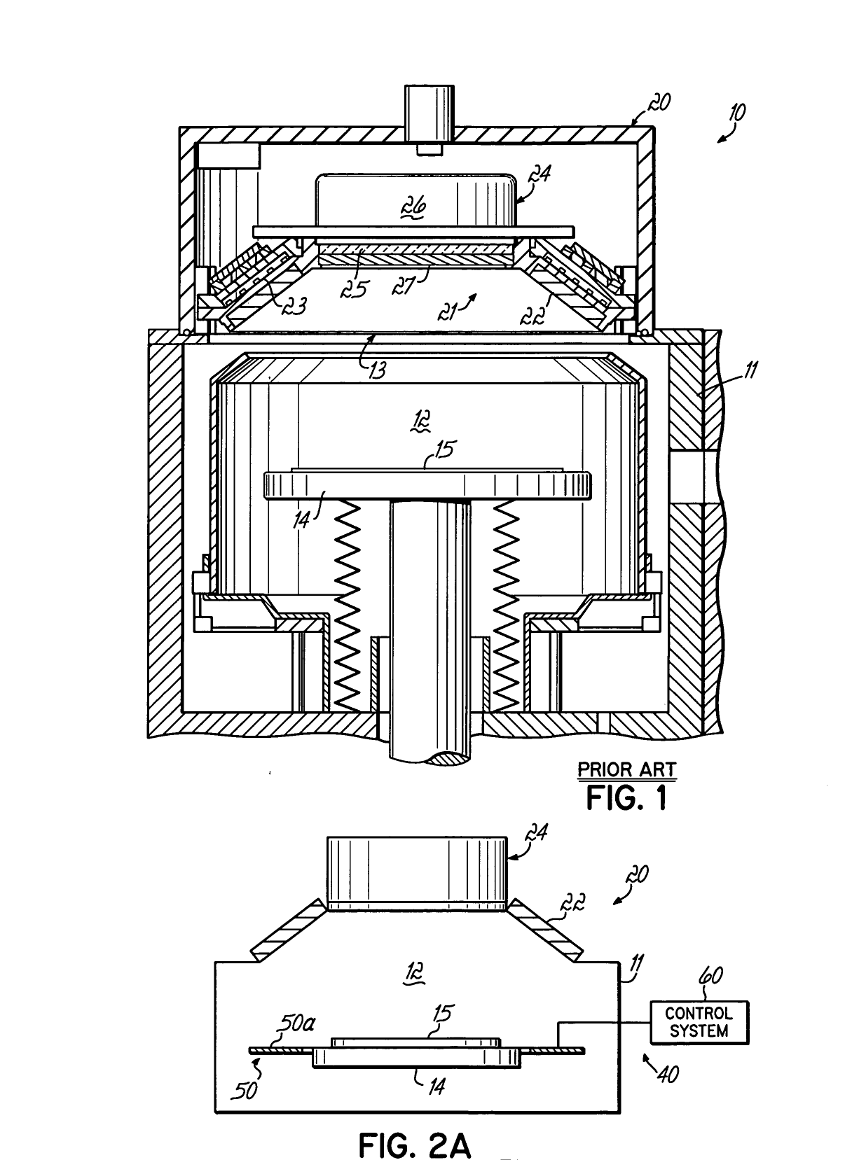

The concepts of the present invention can be used in various plasma processing systems, such as those for performing sputter etching and deposition processes, plasma-enhanced CVD (PECVD) processes, ionized PVD (iPVD) processes, and reactive ion etching processes (RIE). They are particularly applicable for use in iPVD systems for performing standard and thermalized processes, such as, for example, processes employing an apparatus 10 that is illustrated in FIG. 1. Examples of semiconductor wafer processing machines of the iPVD type are described in U.S. Pat. Nos. 6,080,287, 6,287,435 and 6,719,886, each hereby expressly incorporated by reference herein. Embodiments of the present invention are described in the context of the apparatus 10 of FIG. 1, even though applicable to other types of systems.

The iPVD apparatus 10, as illustrated, includes a vacuum processing chamber 12 enclosed in a chamber wall 11 having an opening 13 at the top thereof in which is mounted an ionized sputtering material source 20, which seals the opening 13 to isolate the vacuum within the chamber 12 from external ambient atmosphere. Within the chamber 12 is a wafer support 14 that holds a semiconductor wafer 15 with a side thereof to be processed facing the opening 13. The ionized material source 20 includes a magnetron cathode assembly 21 that includes an annular target 22, which is the source of the coating material, typically, but not necessarily, a metal. The cathode assembly also includes a power supply (not shown) for applying a negative DC sputtering potential to the target 22 and a permanent magnet assembly 23 situated behind the target 22, which traps electrons energized by the DC potential over the surface of the target 22 to form a primary plasma that produces ions in the gas within the chamber to sputter material from the target 22.

In the source 20, the target 22 is annular and surrounds a dielectric window 25, typically formed of quartz or alumina, that is sealed to the target 22 at its center. The target 22 and the window 25 form part of a vacuum enclosure for the chamber 12 along with the chamber wall 11. An RF ICP source 24 is situated at the window 25 and couples RF energy into the chamber 12 to energize a secondary high-density inductively coupled plasma within the chamber 12. The RF ICP source 24 includes an antenna or coil 26 situated on the atmospheric side of the window 25 and a deposition baffle or shield 27 that covers the window 25 on the inside of the chamber 12. An RF generator (not shown) is connected across the leads of the antenna 26 through a suitable matching network. Typically, the RF generator operates at the industrial frequency of 13.56 MHz. Pressures in the chamber 12 for iPVD usually fall in the range from 10 mTorr to 150 mTorr.

In standard PVD and iPVD systems, where processes are performed at lower pressures and gas densities, sputtered particles proceed with a certain kinetic energy from the target toward and onto the substrate in generally straight lines. These particles arrive in a distribution onto the substrate that is, in part, a function of the target and substrate relative geometries. In thermalized systems, higher pressures and gas densities are employed that result in a number of collisions of sputtered material and gas atoms between the target and substrate such that the sputtered material loses its initial kinetic energy until its energy is essentially that due solely to its temperature at that of the background gas. This material is randomized in the plasma, and is directed onto the substrate across the plasma sheath. Depending on chamber dimensions and other geometry, thermalized processes occur at pressures beginning in the range of 30 mTorr to 50 mTorr up to over 100 mTorr.

For iPVD using the system of FIG. 1, a deposition-etch sequential process performed in a single chamber has been found beneficial. One such process is described in U.S. Pat. No. 6,755,945, hereby expressly incorporated by reference herein. According to that patent, a process and an apparatus are provided in which sequential deposition and etching steps are used to solve the problems encountered in coating high aspect ratio sub-micron feature devices. The dep-etch process involves first depositing a thin layer of metallization, for example, tantalum (Ta), tantalum nitride (TaN) or copper (Cu), and then, preferably, after stopping the deposition, performing an ion etch step, preferably by ionized gas, for example, argon (Ar). The etching step removes less material on both the field area on the top surface of the wafer and the via bottom than is deposited during the deposition step, and thus there is net deposition at the end of the process cycle. The deposition-etch cycle can be repeated as many times as needed to achieve the desired result. By balancing the deposition and etching times, rates and other deposition and etch parameters, the overhang growth is eliminated or minimized. The overhang and bottom deposition is etched back and redistributed at least partially to the sidewalls.

Processing systems such as system 10 are designed with maximum care and computer simulation, but in many cases, performing a real process in a plasma reveals the impact of some hardware components and their interaction with plasma on the uniformity of processing at the wafer. For example, non-uniformity can be generated when changing processing conditions, for example, by interaction of the static magnetic field from the magnets 23 of the metal source 20, the geometry of the antenna of the ICP source 24 and RF feed locations, the thermal and RF performance of the substrate holder 14, deposition shields, gas flow, secondary plasma instabilities, the combination of several different plasma processes inside chamber 12, etc.

In sequential deposition and etch processes at the higher pressures at which thermalized plasmas are generated, redeposition of material during the etch portion of the cycle occurs to a greater degree than at lower pressures. The net etching that occurs is the difference of the etch rate, which is fairly uniform, and the redeposition rate, which is observed to be fairly uniform over the center of the wafer but falls off at the edges of the wafer. The effects at the wafer edge are influenced by chamber structures around the perimeter of the chamber, which may not be constant around the wafer circumference, resulting in non-uniformities that vary around the wafer. A perimeter focus ring alters the non-uniformity over the radius of the wafer by extending the radius at which redeposition drops off to beyond the wafer edge. A simple ring does not correct for circumferential or azimuthal non-uniformities.

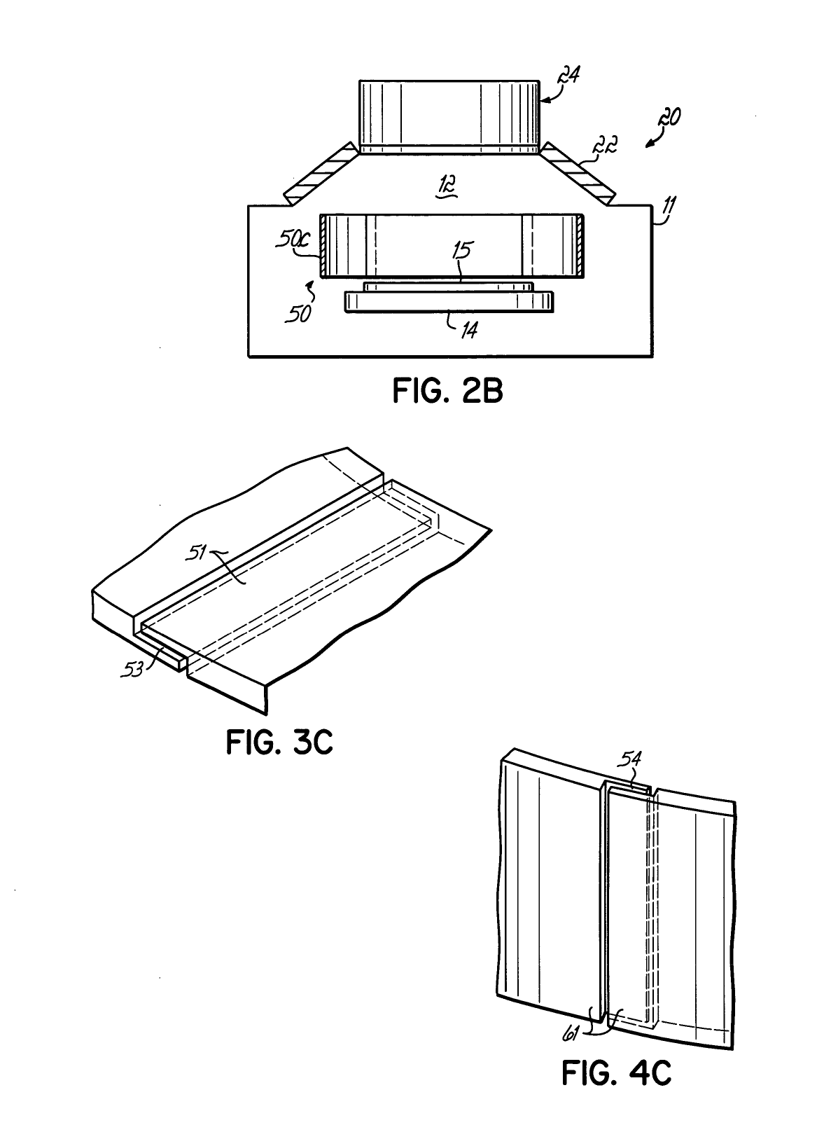

These non-uniformities are minimized by provision of an additional control parameter through a perimeter bias control system 40. One such control parameter has been proposed by applicant in U.S. patent application Ser. No. 10/873,908, filed Jun. 22, 2004, hereby expressly incorporated by reference herein. In accordance with the present invention, the system 40 includes a biased electrode 50 and a controller 60 as illustrated in FIG. 2A in which the biased electrode 50 is in the form of an annular bias ring 50a. The perimeter bias control system 40 creates uniform conditions at the wafer 15 to improve symmetry coverage and uniformity at the wafer 15 by offsetting the effects of those chamber components and process events that would tend to produce asymmetry and non-uniformity. The biased electrode 50 has the benefits of a single continuous biased ring or focusing ring in overcoming axially asymmetric effects, thereby improving radial uniformity. A similar effect can be produced with an alternative version of a biased electrode 50 illustrated in FIG. 2B in which the biased electrode 50 is in the form of a cylindrical ring 50c. While continuous rings don't improve azimuthal non-uniformity, the bias electrode 50 is a segmented electrode in which the segments are selectively biased or otherwise separately controlled by the controller 60 in such a way as to allow azimuthal control of the azimuthal non-uniformity. Peripheral segments of the electrode 50 are electrically biased around the wafer 15 to control the flux from the plasma, changing the ratio of the biased surface area exposed by plasma, thus affecting the symmetry of the plasma column inside the processing chamber 12.

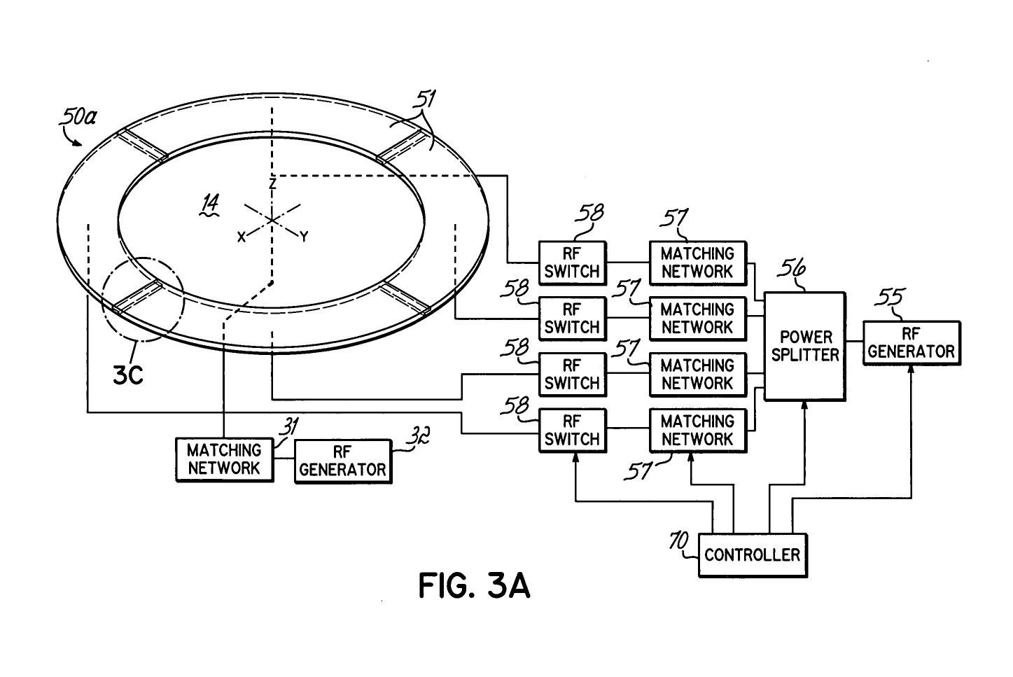

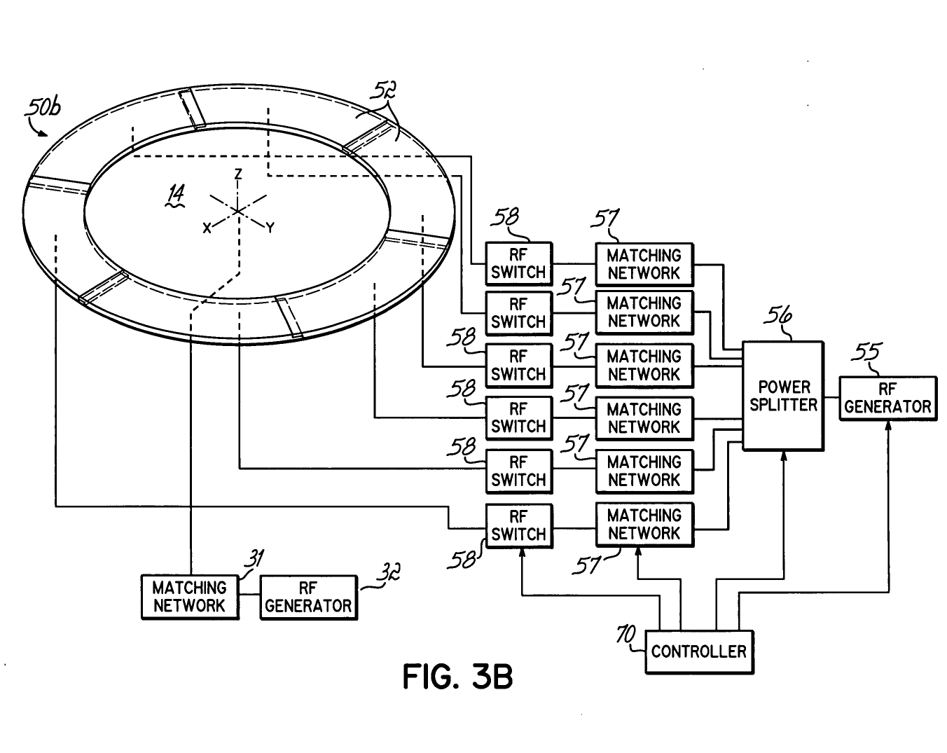

The electrode 50 is provided with a minimum of three segments, as the electrode 50a illustrated in FIG. 3A, which has four 90-degree segments 51. The segments 51 are selectively biased by the controller 60 to create a rotational effect on the plasma column. To provide more effective control of plasma uniformity, more segments can be used, such as the six 60-degree segments 52 of electrode 50b illustrated in FIG. 3B. A higher number of segments can be used as well, but add more complexity, and additional wiring and can reduce the effective segment area and impact on the plasma column spread from its vertical axis, so approximately 6-8 segments are the upper practical limit.

The segments 51, 52 are biased at various cycling frequencies, various duty cycles, various phase shifts, or various combinations of different frequencies, duty cycles and phase shifts. In this way completely customized effect on the plasma column can be produced to compensate for azimuthal non-uniformities that may otherwise be present in a particular plasma processing system. Either RF (1-50 MHz) or DC power can be applied to the segments 51,52 to power the segments, which can cycle at from 1 Hz to tens of kilohertz.

The plasma processing system 20 has the substrate holder 14 connected through a matching network 31 to RF generator 32. FIG. 3A shows four segments 51 of a biased ring 50a, which surround the wafer holder 14. The individual segments 51 are electrically insulated by a gap 53 (see FIG. 3C). Each segment 51 is connected to an RF power generator 55 through power splitter 56 that provides an equal portion of the RF power to each segment 51. Outputs from the power splitter 56 are connected through matching networks 57 and RF switches 58 to the individual segments 51.

FIG. 3B shows a similar device that consists of six planar segments 52. The wafer 15 on the holder 14 is surrounded by electrode segments 52 that geometrically constitute the segmented ring 50b. Individual segments 52 are also electrically insulated from each other by the gap 53 of FIG. 3A. Each segment 52 is connected to the RF power generator 55 through power splitter 56 that provides equal portion of the RF power to each segment 52. Outputs from power splitter 56 are connected through matching networks 57 and RF switches 58 as with the ring 50a of FIG. 3A.

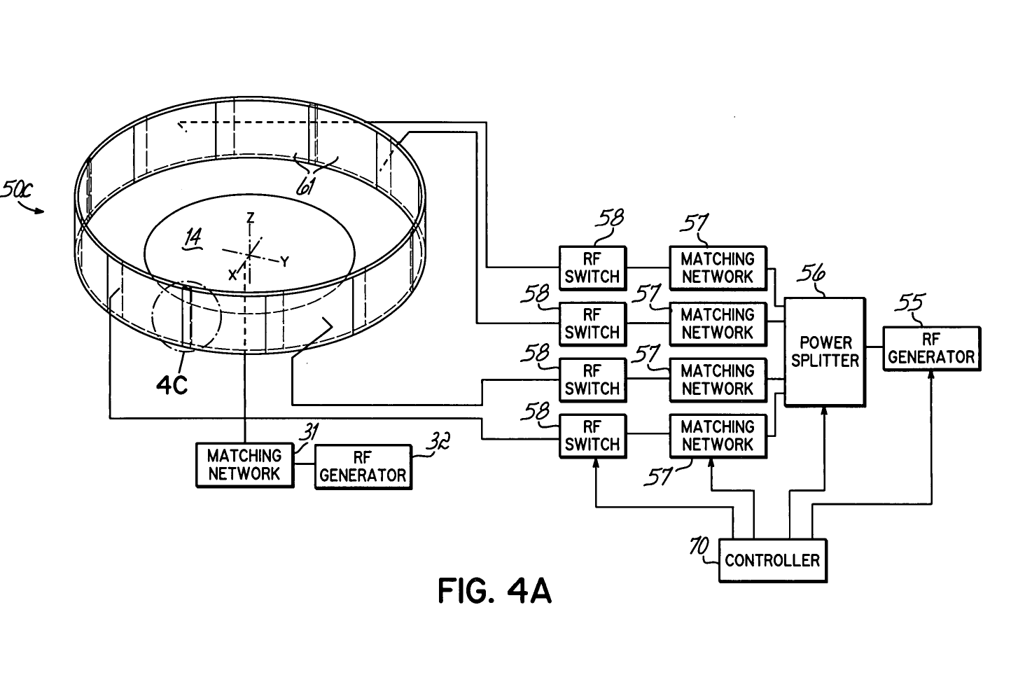

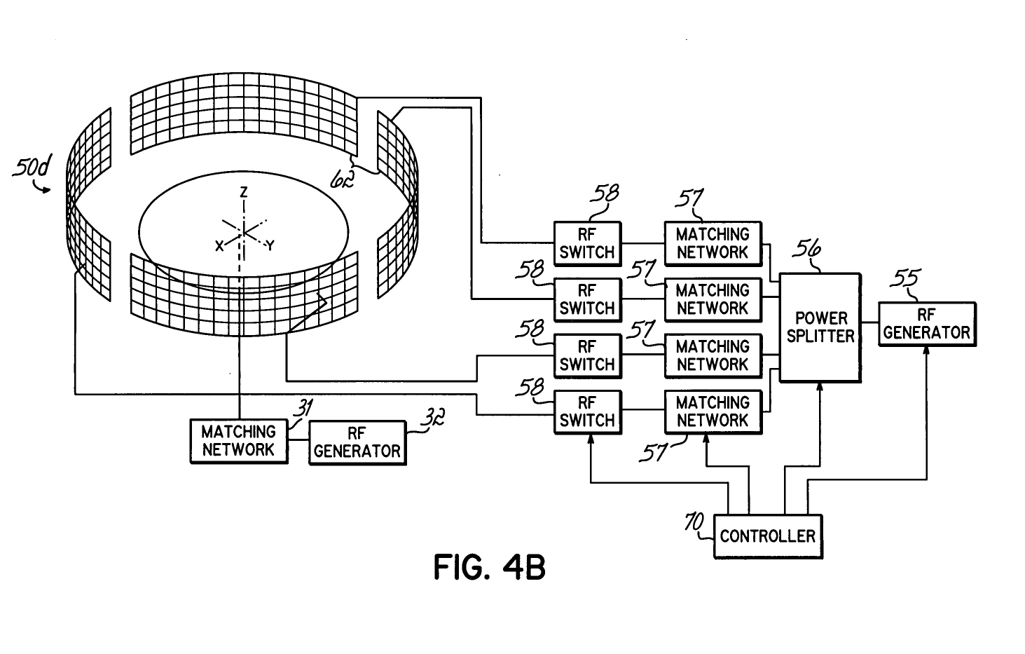

FIG. 4A shows a similar device 50c that has four cylindrical segments 61. The wafer 15 on the holder 14 is surrounded by electrode segments 61 that geometrically constitute the segmented surface area around the wafer. Individual segments 61b are electrically insulated by a gap 54 (see FIG. 4C). Each segment is similarly connected to the RF power generator 55 through the power splitter 56 that provides equal portion of the RF power to each segment. Outputs from the power splitter 56 are connected through matching networks 57 and RF switches 58 to individual segments 61.

Because the surface area of the segmented device 50 is comparable or larger than the area of the wafer 15, and it is biased, the re-sputtering of the surface or coatings deposited on the surface of the device 50 can occur. This re-sputtering can contribute to a re-deposition on the wafer 15. To avoid or reduce this re-sputtering from segmented electrode 50c to the wafer 15, the segmented device 50c can be made in the form of grid 50d, as illustrated in FIG. 4B. Similar effects will be produced using a perforated electrode. FIG. 4B shows a device 50d that consists of four cylindrical segments 62 in a form of wired grid. A planar-segmented grid can be used, or a combination of planar and cylindrical segmented electrode segments, either as a continuous surface such as of segments 61 or in a grid form as with segments 62.

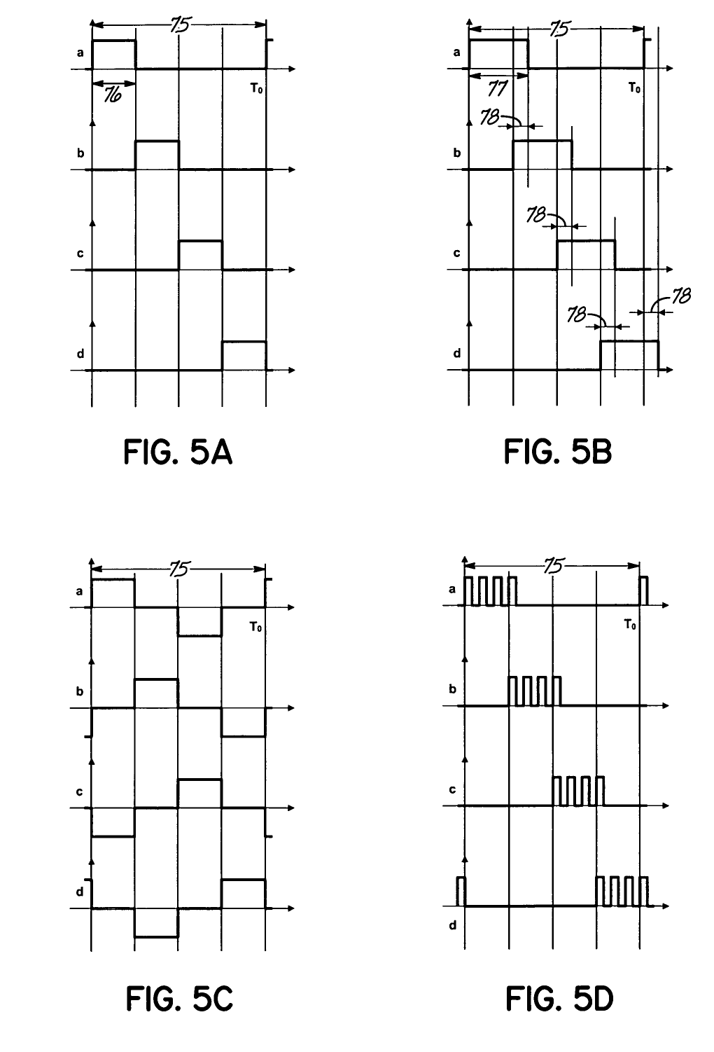

Individual segments 51, 52, 61 or 62 are biased by RF power in sequence, for example, as shown in the graph of FIG. 5A. Such a sequence creates an electric field that rotates around the wafer and interacts with the plasma, offsetting the plasma column offset inside the chamber 12. The length of the cycle period 75 is chosen such that multiple rotations will occur within the processing time for a given wafer. That means that the individual segments are pulsed at least several Hz with a duty cycle 76 of 25% for the four segment rings 50a, 50c and 50d, with a similar phase shift between adjacent segments. A duty cycle of about 17% and similar phase shift will occur for the six segment configurations 50b. However, the duty cycle for each individual segment can be increased or reduced or overlapping electric fields on neighboring segments can be generated to compensate the azimuthal non-uniformity in particular process. The duty cycles and other operation of the system are controlled by a controller 70. The typical range for a duty cycle may be, for example, from 20% to 50% for a four segment element 50 or from 10% to 60% for a six segment system. The illustration of an increased a duty cycle 77 for four-segmented biased ring, as for example in FIG. 5B, allows for an overlapping period 78 when two neighboring segments are biased simultaneously, thus making effective an area twice as large, having a stronger effect on the plasma column.

Typical cycling frequency is from 1 to 100 Hz, however, it can be extended up to 1 kHz or several tens of kHz. The timing is typically chosen to provide that all segments will be sequentially turned on within one cycle, but that is not necessary.

The biasing of the segments can be provided either by RF power or by pulsing DC power. FIG. 5C shows an example of bipolar biasing of two opposite segments creating cooperating forces on the plasma column along one radial direction given by biased segments.

FIG. 5D shows another pulsing sequence with each segment biased at a pulsing frequency and modulated. For all above described embodiments the power level of supply for a segmented bias device is typically in a range from 100 watts to several kW. Frequency range is from 1 MHz to 50 MHz or using pulsed DC, mono- or bi-polar supplies. Some segments can stay at floating potential during operation.

A microprocessor based controller 70 controls the pulsing sequence of the individual segments. Different segments can be energized for different duty cycles, producing an asymmetry that can be structured to compensate for azimuthal non-uniformities.

For some applications, to deal with azimuthal nonuniformity, it is advantageous to use multiple segments with variable angular lengths or different coupling ratios to the RF power or combinations of these concepts. For example, the RF power from the generator could be split into only two main lines, with each line connected to several segments. By providing different angular lengths of the segments or different areas or other electrical properties of the individual segments around the wafer perimeter, a non-linear impact on the redeposition effect can be generated so as to adjust for any specific nonuniformity in the azimuthal profile of the plasma process. Alternatively, variation of the electrical characteristics of the energy delivered to the segments, such as voltage, frequency, waveform, etc., can be used to shape the correcting effect of the electrode on the deposition or other processing profile.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A system for reducing non-uniformities in a semiconductor plasma processing apparatus comprising:
a ring-shaped electrode dimensioned to encircle a substrate support, the electrode being formed of a plurality of at least three segments;
an electrical energy supply coupled to each of the segments of the electrode; and
a controller coupled to the energy supply and programmed to control the supply to sequentially energize the segments of the electrode to affect the processing of the substrate non-uniformly around the circumference of the substrate support.

2. The system of claim 1 wherein:
the controller is programmed to vary the duty cycles of energy applied to the segments of the electrode.

3. The system of claim 1 wherein:
the controller is programmed to sequentially energize a plurality of the segments through a plurality of cycles around the substrate support.

4. The system of claim 1 wherein:
the supply includes an RF generator coupled to each of the segments of the electrode.

5. The system of claim 1 wherein:
the supply includes an RF generator selectively couplable to each of the segments of the electrode.

6. The system of claim 1 wherein:
the electrode includes four to six segments electrically isolated from each other and surrounding the substrate support.

7. The system of claim 6 wherein:
the electrode is an annular disk.

8. The system of claim 6 wherein:
the electrode is a cylinder.

9. The system of claim 8 wherein:
the segments are formed of a mesh.

10. An iPVD apparatus comprising the system of claim 1.

11. A semiconductor wafer processing apparatus comprising:
a vacuum processing chamber;
a sputtering target in the chamber;
a high-density plasma source coupled to the chamber;
a substrate support in the chamber;
a ring-shaped electrode encircling the substrate support, the electrode being formed of a plurality of at least three segments;
an electrical energy supply coupled to the segments of the electrode; and
a controller coupled to the energy supply and configured to sequentially energize the segments of the electrode.

12. The apparatus of claim 11 wherein:
the controller is programmed to energize the segments of the electrode so as to affect the processing of the substrate non-uniformly around the circumference of the substrate support so as to reduce azimuthal non-uniformities in the processing of the substrate.

13. A method of improving azimuthal uniformity of a film in an ionized physical vapor deposition process, the method comprising:
encircling a substrate support with a segmented element; and
cyclically energizing the segmented element by sequentially coupling electrical energy to segments thereof.

14. The method claim 13 wherein:
the element includes at least three segments; and
the energizing of the element includes biasing each of the segments in a sequence through each of a plurality of cycles.

15. The method claim 13 further comprising:
controlling the duty cycles of the coupling of the energy to the segments to reduce azimuthal non-uniformities on the substrate.

16. The method claim 15 wherein:
the controlling of the duty cycles includes coupling the energy to different segments differently to reduce azimuthal non-uniformities on the substrate.

17. The method claim 13 further comprising:
performing a series of deposition and etch processes sequentially on the substrate.

18. The method claim 13 further comprising:
energizing different segments of the element differently to reduce azimuthal non-uniformities on the substrate.
